(19) United States
(12) Patent Application Publication
(10) Pub. No.: US 2008/0258167 A1
(43) Pub. Date: Oct. 23, 2008

(54) PACKAGE STRUCTURE FOR LIGHT-EMITTING ELEMENTS

(76) Inventors: Ming-Dah Liu, Hsinchu (TW); Chia-Hung Hsu, Hsinchu (TW)

Correspondence Address: SINORICA, LLC, 528 FALLSGROVE DRIVE, ROCKVILLE, MD, 20850, US

(21) Appl. No.: 11/738,564

(22) Filed: Apr. 23, 2007

(51) Int. Cl. H01L 31/00

(52) U.S. Cl. 257/99; 257/E33.056

(57) ABSTRACT

The present invention discloses a package structure for light-emitting elements, wherein a horizontally-extending thermal conductive plate contacts a thermal conductive substrate having a larger heat-dissipating area. Via such a horizontal heat-dissipation mechanism, the heat generated by light-emitting elements is dissipated at a higher rate; thereby, the light-emitting elements have a higher working efficiency and a longer service life.

### BACKGROUND OF THE INVENTION

1. Field of the Invention

The present invention relates to a package structure, particularly to a package structure for light-emitting elements.

2. Description of the Related Art

No matter what kind of end-product is, LED (Light-Emitting Diode) has to confront the problems of heat dissipation, power consumption, color rendering index, chrominance uniformity, etc. However, the solutions thereof are distinct in different application fields. In the illuminator and automobile industries, the quantity of LED used in a light is hundreds times more than that used in the backlight module of a common mobile phone. Therefore, heat-dissipation of LED is critical for higher driving current. The common solution thereof is to directly dispose LED chips on a high-thermal conductivity metallic substrate, i.e. the so-called COB (Chip On Board) packaging technology, wherein the metallic substrate is connected with a thermal conductive terminal for heat dissipation.

Refer to FIG. 1(a) and FIG. 1(b) respectively a perspective exploded view and a sectional view showing a conventional vertical-stack type LED package structure. As shown in the drawings, a cup 22 is located on a base 24, a metallic circuit substrate 18 is arranged on the cup 22, and a LED chip 16 is stuck onto the metallic circuit substrate 18 with an thermal conductive glue. An optical lens 10 covers the LED chip 16, and an embedded cast surrounds the LED chip 16. A plurality of electrodes 14 extends to the exterior of the package structure, and wires 20 interconnect the LED chip 16 and the electrodes 14. In such a conventional vertical-stack LED package structure, the heat generated by the LED chip 16 can only be vertically conducted to the metallic circuit substrate 18 and then therefrom dissipated to the exterior. Therefore, the fabrication cost of the metallic circuit substrate 18 is pretty high; moreover, the stability of the fabrication process of the metallic circuit substrate 18 is not so well. Besides, the conventional LED package structure is partially made of the resin with a low thermal conductivity. Thus, the heat-dissipation effect of the conventional LED package structure is inferior.

### SUMMARY OF THE INVENTION

One objective of the present invention is to provide a package structure for light-emitting elements, wherein the light-emitting module and the circuit substrate, which accumulate heat during operating, are joined with a thermal conductive plate and a thermal conductive substrate, which are horizontally arranged. The heat generated by the light-emitting elements is conducted to the thermal conductive plate, transferred to the thermal conductive substrate and then rapidly dissipated from the thermally conductive substrate to the exterior. As it is unnecessary to conduct heat via the circuit substrate, the present invention greatly promotes the heat-dissipation efficiency.

Another objective of the present invention is to provide a package structure for light-emitting elements, wherein a circuit substrate and a thermally conductive substrate are horizontally joined together to function as the substrate of a light-emitting module, which not only efficiently dissipates heat fast but also implements circuit connection. Such a substrate takes the place of the conventional expensive metallic circuit board fabricated with a complicated process. Thus, the present invention reduces the cost and improves the yield.

To achieve the abovementioned objective, the present invention comprises: a substrate structure, at least one thermal conductive plate, and at least one light-emitting module. The substrate structure includes: a circuit substrate and a thermal conductive substrate, wherein the circuit substrate and the thermal conductive substrate are side-by-side, or so-called horizontally, joined together. One side of the thermal conductive plate is disposed above the circuit substrate, while the other side horizontally extends on the thermal conductive substrate. Thus, the thermal conductive plate spans the circuit substrate and the thermal conductive substrate. The thermal conductive plate is securely fixed to the thermally conductive substrate with screws or an adhesive. The light-emitting module includes: a plurality of LED chips, a plurality of wires, a plurality of electrodes, and an encapsulant. The LED chips are horizontal-separately located on the thermal conductive plate. An insulating material may be applied to the interface between each LED chip and the thermal conductive plate for avoiding a short circuit. The wires interconnect the LED chips and the electrodes, the encapsulant covers the LED chips and the wires, and the electrodes extend from the interior of the encapsulant to the exterior of the encapsulant. The circuit substrate has a plurality of integrated circuits, and the LED chips are electrically connected to the integrated circuits via the wires and the electrodes connected with the wires. In the present invention, the heat generated by the LED chips is conducted to the thermal conductive plate and then transferred to the thermal conductive substrate. Then, the larger-area thermal conductive substrate dissipates the heat accumulating in the LED chips or the circuit substrate via conduction, convection or radiation; therefore, the heat accumulated within the light-emitting module or the circuit substrate is greatly reduced.

Other objectives, features and advantages of the present invention will be further understood from the further technology features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1(a) is a perspective exploded view schematically showing a conventional vertical-stack type LED package structure.

FIG. 1(b) is a sectional view of the package structure shown in FIG. 1(a).

FIG. 2(a) is a sectional view schematically showing the package structure for light-emitting elements according to one embodiment of the present invention.

FIG. 2(b) is a perspective view of the package structure shown in FIG. 2(a).

FIG. 3 is a top view schematically showing the package structure for light-emitting elements according to another embodiment of the present invention, wherein the package structure has a plurality of light-emitting modules.

FIG. 4 is a sectional view schematically showing the package structure for light-emitting elements according to yet another embodiment of the present invention.

FIG. 5(a) to FIG. 5(d) are top views schematically showing the package structure for light-emitting elements according to still another embodiment of the present invention, wherein the package structure has three LED chips.

FIG. 6(a) to FIG. 6(c) are top views schematically showing the package structure for light-emitting elements according to further another embodiment of the present invention, wherein the package structure has four LED chips.

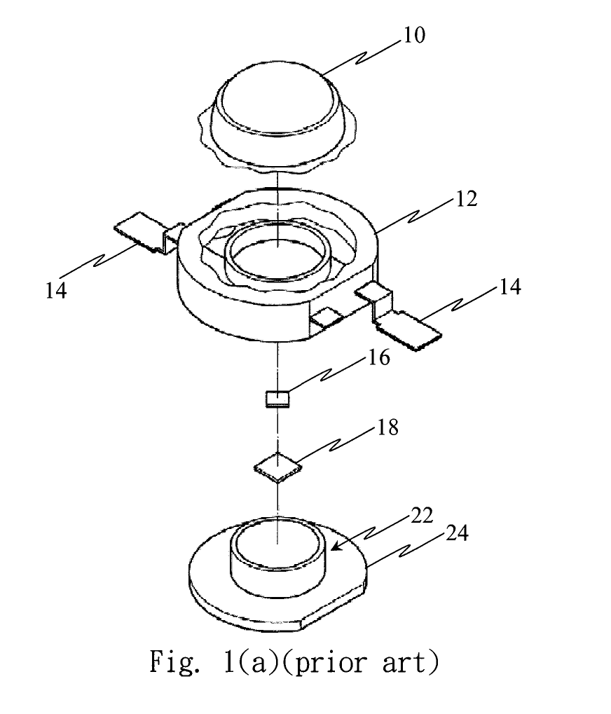

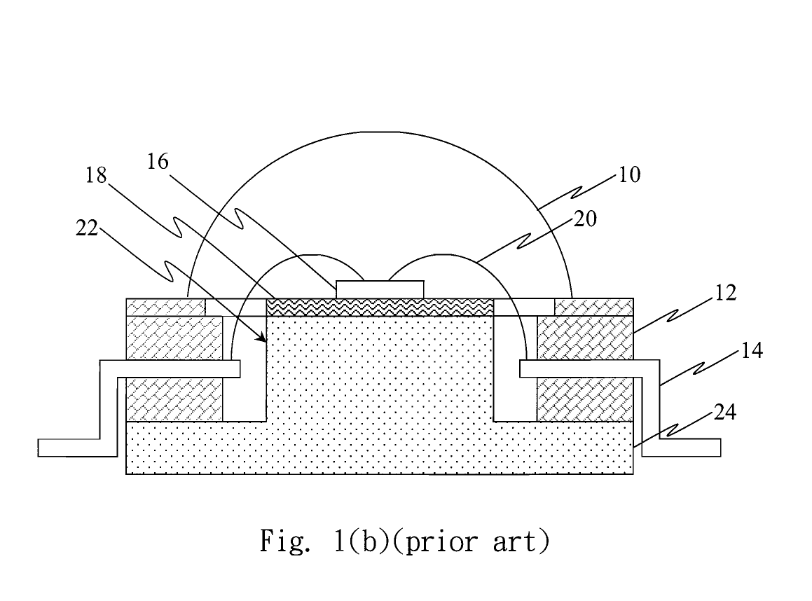

### DETAILED DESCRIPTION OF THE INVENTION

In the following detailed description of the preferred embodiments, reference is made to the accompanying drawings which form a part hereof, and in which is shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component facing “B” component directly or one or more additional components is between “A” component and “B” component. Also, the description of “A” component “adjacent to” “B” component herein may contain the situations that “A” component is directly “adjacent to” “B” component or one or more additional components is between “A” component and “B” component. Accordingly, the drawings and descriptions will be regarded as illustrative in nature and not as restrictive.

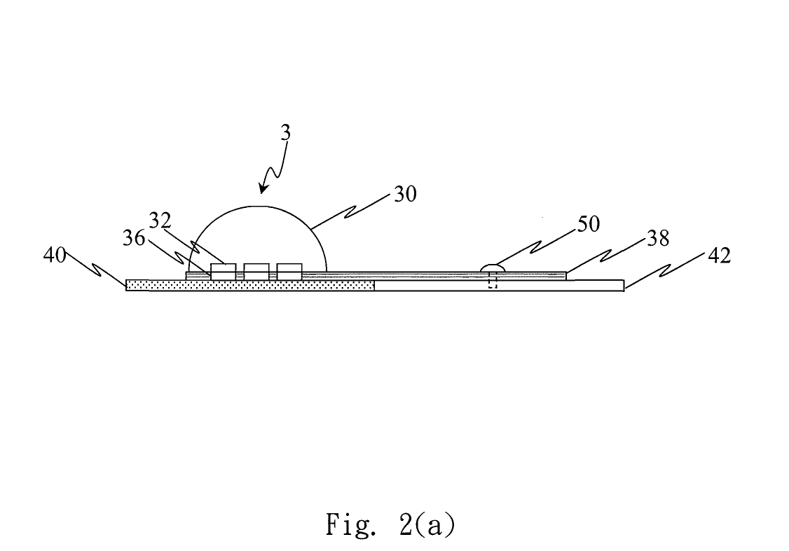

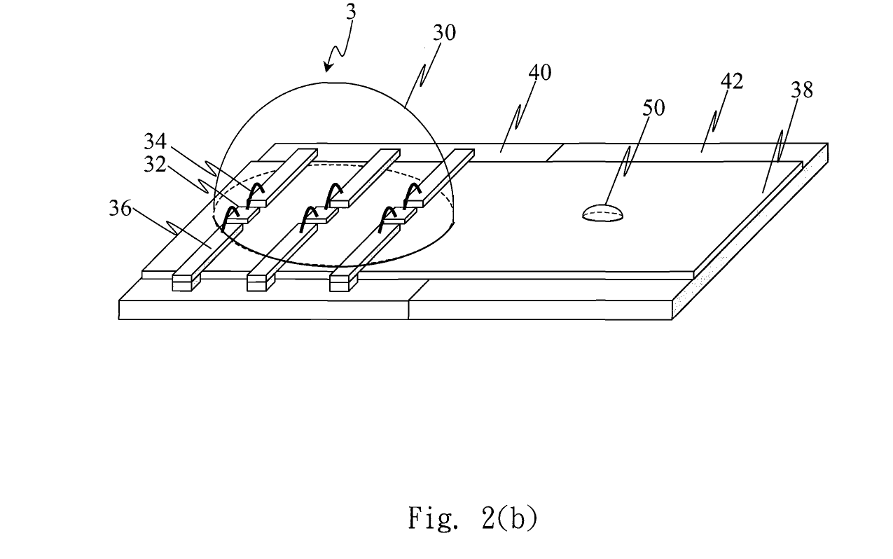

Refer to FIG. 2(a) and FIG. 2(b) respectively a sectional view and a perspective view schematically showing the package structure for light-emitting elements according to one embodiment of the present invention. In this embodiment, the package structure for light-emitting elements comprises: a substrate structure, at least one thermal conductive plate 38 and at least one light-emitting module 3. The substrate structure includes: a circuit substrate 40 and a thermal conductive substrate 42. The circuit substrate 40 and the thermal conductive substrate 42 are side-by-side, or horizontally, joined to form the substrate structure. The circuit substrate 40 may be a common printed circuit board, and the material thereof is usually a fiber-reinforced plastic, a copper foil, a low temperature cofired ceramic, or an aluminum nitride. The material of the thermal conductive substrate 42 may be a high thermal conductivity material, such as copper, aluminum, carbon fiber, a ceramic material, or a metallic alloy (e.g. a copper-tungsten alloy).

The thermal conductive plate 38 is located on the circuit substrate 40 and the thermal conductive substrate 42. One side of the thermal conductive plate 38 is disposed on the circuit substrate 40, and the other side extends horizontally on the top surface of the thermal conductive substrate 42. Thus, the thermal conductive plate 38 spans both the circuit substrate 40 and the thermal conductive substrate 42. The thermal conductive plate 38 may be an aluminum nitride plate, a low temperature cofired ceramic plate, a ceramic film, a diamond film, or metal plate The thermal conductive plate 38 is securely fixed to the thermal conductive substrate 42 with a screw 50 or an adhesive.

The light-emitting module 3 includes: a plurality of LED chips 32, a plurality of wires 34, a plurality of electrodes 36 and an encapsulant 30. Those LED chips 32 are horizontal-separately located on the surface of the thermal conductive plate 38. An insulating material may be applied to the interface between each LED chip 32 and the thermal conductive plate 38 for preventing a short circuit. The wires 34 interconnect the LED chips 32 and the electrodes 36. The encapsulant 30 covers the LED chips 32 and the wires 34, and the material thereof may be epoxy or a silicon-containing resin. The electrodes 36 extend from the interior of the encapsulant 30 to the exterior of the encapsulant 30. The circuit substrate 40 has a plurality of integrated circuits. The LED chips 32 are electrically connected to the integrated circuits via the wires 34 and the electrodes 36 connected with the wires 34. The material of the integrated circuit may be silicon, germanium, or a combination of silicon and germanium.

The heat generated by the LED chips 32 is conducted to the thermal conductive plate 38 and then transferred to the thermal conductive substrate 42. For a considerable area of the thermal conductive substrate 42, the heat from the temperature gradient between the thermal conductive substrate 42 and the environment are rapidly dissipated. Therefore, the present invention greatly reduces the heat accumulating in the LED chips 32 or the circuit substrate 40. In the present invention, the thermal conductive plate 38 takes the place of the conventional metallic circuit board; thus, a circuit substrate of a lower cost but with a lower thermal conductivity is enough to meet the requirement of the package structure. Therefore, the present invention reduces the cost of materials.

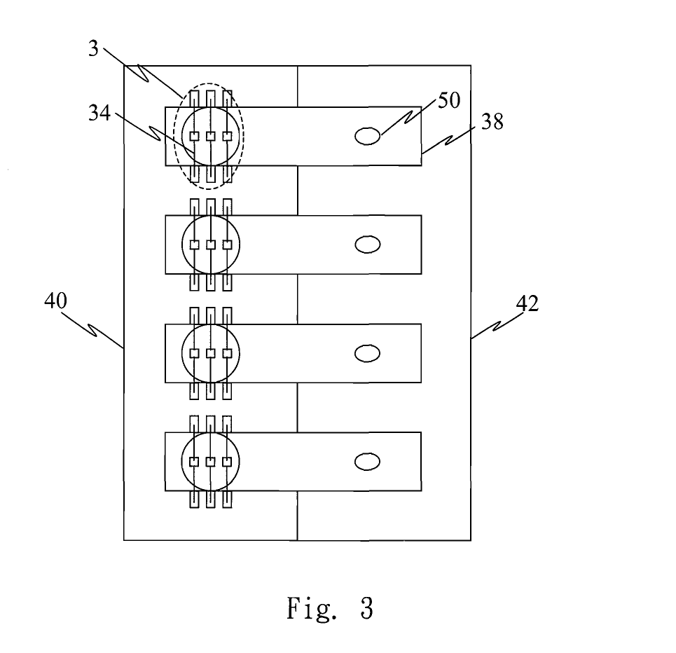

Refer to FIG. 3 for another embodiment of the present invention. The package structure for light-emitting elements of the present invention may otherwise comprise: a plurality of light-emitting modules 3 and a plurality of thermal conductive plate 38, and each light-emitting module 3 is disposed on one thermal conductive plate 38, and those light-emitting modules 3 are discretely and parallel arranged on the circuit substrate 40.

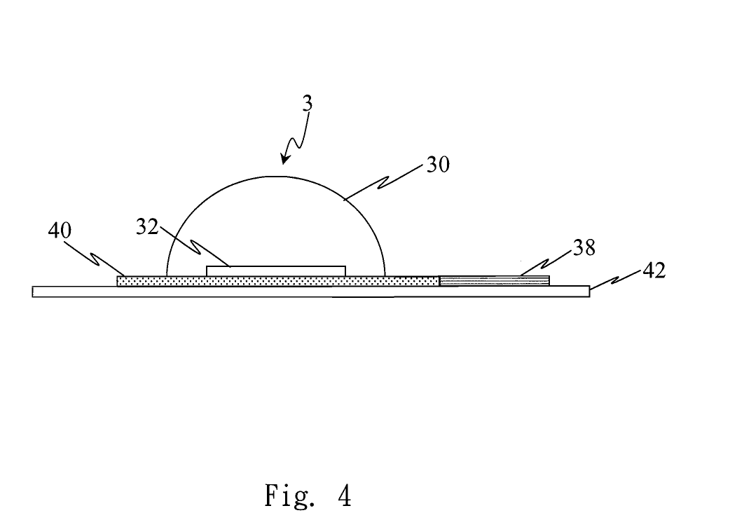

Refer to FIG. 4 a sectional view schematically showing the package structure for light-emitting elements according to yet another embodiment of the present invention. In this embodiment, the package structure for light-emitting elements comprises: a thermal conductive substrate 42, a circuit substrate 40, a thermal conductive plate 38 and a light-emitting module 3. The thermal conductive plate 38 and the circuit substrate 40 are side-by-side, or horizontally, located on the thermal conductive substrate 42. The light-emitting module 3 includes at least one LED chip 32, and the LED chip 32 is stuck onto the circuit substrate 40. The heat generated by the LED chip 32 is vertically conducted to the circuit substrate 40, which is electrically connected with the LED chip 32, and then horizontally transferred to the thermal conductive plate 38; then, the heat generated by the LED chip 32 is rapidly conducted to the thermal conductive substrate 42. Therefore, when the LED chip 32 is working, heat neither accumulates around the LED chip 32 nor accumulates in the circuit substrate 40. Thus, the operational temperature is reduced, and the operational stability is promoted.

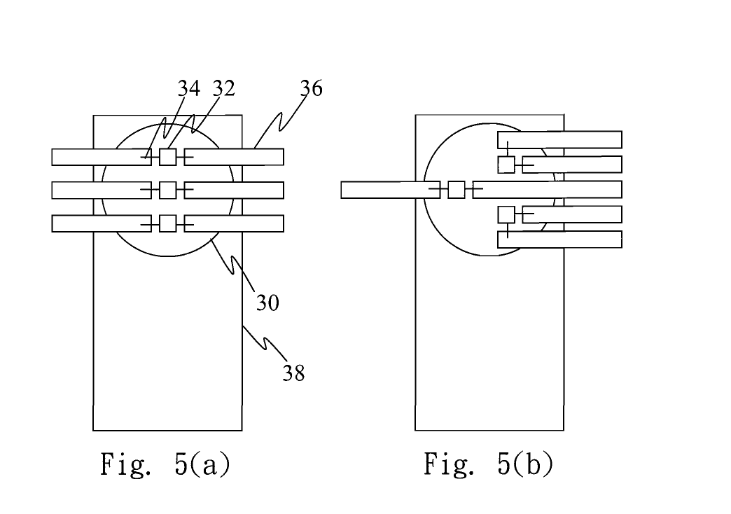

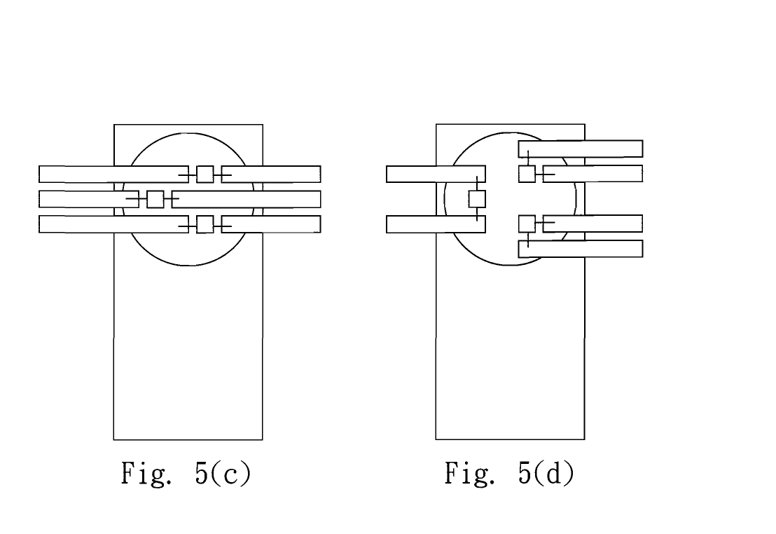

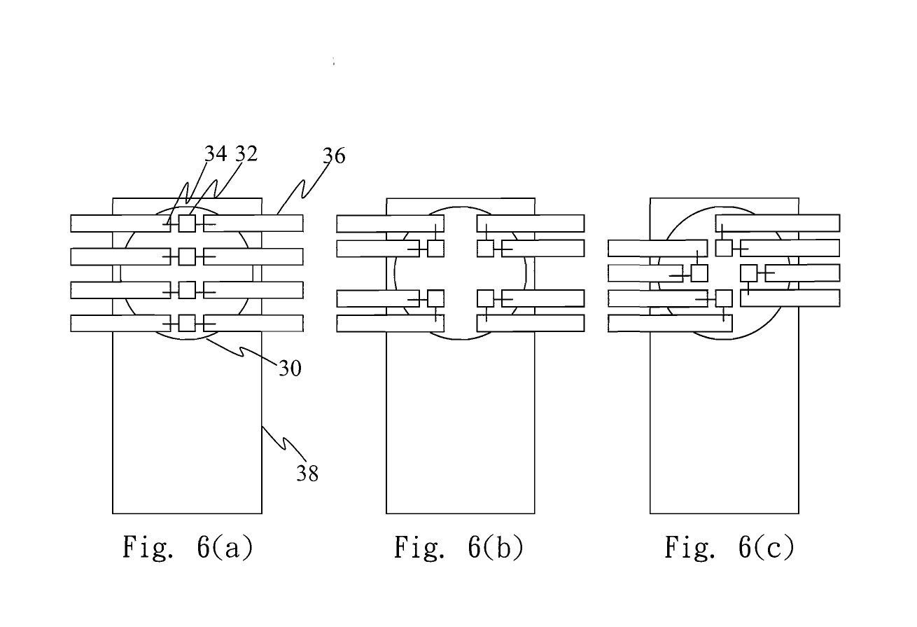

Refer to from FIG. 5(a) to FIG. 5(d) top views schematically showing the package structure for light-emitting elements according to still another embodiment of the present invention. In this embodiment, three LED chips 32—a red one, a green one and a blue one—are used to generate white light. Those three LED chips 32 may be linearly arranged, as shown in FIG. 5(a). Otherwise, those three LED chips 32 may be triangularly arranged, as shown in from FIG. 5(b) to FIG. 5(d). Refer to from FIG. 6(a) to FIG. 6(c) top views schematically showing the package structure for light-emitting elements according to further another embodiment of the present invention. In this embodiment, four LED chips 32—a red one, a blue one, and two green one—are used to generate a more intense light. Those four LED chips 32 may be linearly arranged, as shown in FIG. 6(a). Otherwise, those four LED chips 32 may be rectangularly arranged, as shown in FIG. 6(b) and FIG. 6(c).

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A package structure for light-emitting elements, comprising:
a circuit substrate;
at least one thermal conductive plate with one side disposed on said circuit substrate and the other side extending horizontally; and
at least one light-emitting module disposed on a surface of said circuit substrate but.

2. The package structure for light-emitting elements according to claim 1, wherein said light-emitting module includes:
at least one LED chip on said thermal conductive plate;
a plurality of electrodes;
a plurality of wires respectively interconnecting said LED chips and said electrodes; and
an encapsulant covering said LED chip and said wires with said electrodes extending from an interior of said encapsulant to an exterior of said encapsulant.

3. The package structure for light-emitting elements according to claim 2, wherein an insulating material is applied to an interface between said LED chip and said thermal conductive plate.

4. The package structure for light-emitting elements according to claim 2, wherein a plurality of said LED chips is arranged on said thermal conductive plate, and said LED chips are linearly, triangularly, or rectangularly arranged on said thermal conductive plate.

5. The package structure for light-emitting elements according to claim 1, further comprising a thermal conductive substrate, wherein said thermal conductive substrate and said circuit substrate are side-by-side joined, and said other side of said thermal conductive plate extending horizontally on said thermal conductive substrate.

6. A package structure for light-emitting elements, comprising:
a thermal conductive substrate;
at least one circuit substrate on said thermal conductive substrate;
at least one thermal conductive plate on said thermal conductive substrate and joined to said circuit substrate side-by-side; and
at least one light-emitting module on said circuit substrate.

7. The package structure for light-emitting elements according to claim 6, wherein said light-emitting module includes:
at least one LED chip;
a plurality of electrodes;
a plurality of wires respectively interconnecting said LED chips and said electrodes; and
an encapsulant covering said LED chip and said wires with said electrodes extending from an interior of said encapsulant to an exterior of said encapsulant.

8. The package structure for light-emitting elements according to claim 7, wherein an insulating material is applied to an interface between said LED chip and said thermal conductive plate.
